(19) United States
(12) Patent Application Publication
(10) Pub. No.: US 2010/0211207 A1
(43) Pub. Date: Aug. 19, 2010

(54) Manufacturing apparatus for semiconductor device, controlling method for the manufacturing apparatus, and storage medium storing control program for the manufacturing apparatus

(75) Inventor: Takashi Murakami, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/656,560

(22) Filed: Feb. 3, 2010

(30) Foreign Application Priority Data
Feb. 17, 2009 (JP) 34566/2009

(51) Int. Cl. H01L 21/00; G06F 19/00

(52) U.S. Cl. 700/121; 29/25.01

(57) ABSTRACT

The manufacturing apparatus for a semiconductor device includes: a stage information obtaining portion for obtaining stage information that is information for specifying an exposure stage used in an exposure process of a wafer to be heated from an exposure unit including a plurality of exposure stages on which the wafer is placed; and a temperature setting portion for setting heating temperature of a heating apparatus for heating the wafer to be heated. The temperature setting portion sets the heating temperature based on the stage information individually for each of the plurality of exposure stages.

### BACKGROUND OF THE INVENTION

1. Field of the Invention

The present invention relates to a manufacturing apparatus for a semiconductor device, a controlling method for the manufacturing apparatus, and a storage medium storing a control program for the manufacturing apparatus.

2. Description of the Related Art

When a semiconductor device is manufactured, it is desirable that dimensions of formed patterns should accurately agree with target dimensions. However, when a semiconductor device is manufactured, there are various factors that cause a dimension deviation of the formed pattern.

As a factor that causes a dimension variation of a pattern, there is heating temperature in a post exposure bake (PEB) process. When a semiconductor device is manufactured, a resist film made of resin is formed on a film to be processed of a wafer. Then, the resist film is exposed through a photomask in which a predetermined pattern is formed. The wafer after the exposure is heated. This heating process is performed for a purpose of accelerating chemical reaction of the resist film, and is called the post exposure bake process. The wafer is developed after the post exposure bake process. By the development process, a predetermined pattern is formed in the resist film. The heating temperature in the post exposure bake process affects a resist pattern dimension after the development process. For instance, if the heating temperature has a variation within a surface of the wafer, a dimension of a formed pattern may be deviated depending on a position even in the same wafer.

Japanese Patent Application Laid-open No. 2006-228816 (hereinafter, referred to as Patent Document 1) describes a technology for setting temperatures of a heating plate so that line widths of the resist pattern become uniform within a wafer surface. Patent Document 1 describes that the heating plate is divided into a plurality of heating plate regions so that the temperature may be set for each heating plate region. Thus, the resist pattern may be formed uniformly within the substrate surface.

On the other hand, the pattern dimension may also vary in accordance with an exposure condition when the exposure is performed. In connection with this, Japanese Patent Application Laid-open No. 2005-197362 (hereinafter, referred to as Patent Document 2) describes a technology for realizing an exposure process system that may easily prevent a dimension variation within the wafer surface among a plurality of wafers. Patent Document 2 describes that an exposure apparatus is controlled so as to expose the wafer to be processed by using correction data for correcting a dimension variation of the resist pattern within the wafer surface which is caused by a pair of heating apparatus unit and developing apparatus unit that is used for the wafer to be processed among a plurality of pairs of heating apparatus units and developing apparatus units.

The present inventor has recognized as follows. Among the exposure apparatuses, there is an apparatus equipped with a plurality of exposure stages. If the plurality of exposure stages are provided, one exposure stage may be used for the exposure process of one wafer while another exposure stage may be used for various measuring processes or the like of another wafer before exposure. The plurality of exposure stages enable to perform exposure processes in a parallel manner, and hence throughput of exposure may be improved.

Here, the exposure apparatus is equipped with an exposure amount sensor corresponding to each exposure stage. When the exposure process is performed, the exposure amount sensor is used for irradiating the wafer with a desired amount of light. However, the exposure amount sensor has an individual variation. The individual variation of the exposure amount sensor may cause a difference in actual exposure amount among a plurality of exposure stages. There is a problem that this difference in exposure amount causes a difference in formed pattern dimension among the exposure stages.

### SUMMARY

A semiconductor device manufacturing apparatus according to the present invention includes: a stage information obtaining portion for obtaining stage information that is information for specifying an exposure stage used in an exposure process of a wafer to be heated from an exposure unit including a plurality of exposure stages on which the wafer is placed; and a temperature setting portion for setting heating temperature of a heating apparatus for heating the wafer to be heated. The temperature setting portion sets the heating temperature based on the stage information individually for each of the plurality of exposure stages.

A controlling method for a semiconductor device manufacturing apparatus according to the present invention includes: obtaining stage information that is information for specifying an exposure stage used in an exposure process of a wafer to be heated from an exposure unit including a plurality of exposure stages on which the wafer is placed; and setting heating temperature of a heating apparatus for heating the wafer to be heated based on the stage information individually for each of the plurality of exposure stages.

A storage medium storing a control program for a semiconductor device manufacturing apparatus according to the present invention stores a program for realizing the above-mentioned controlling method for the semiconductor device manufacturing apparatus by a computer.

A manufacturing method for a semiconductor device according to the present invention includes: making a wafer to be heated by exposing a wafer on which a resist film is formed, with an exposure unit including a plurality of exposure stages on which the wafer is placed; making a heated wafer by heating the wafer to be heated with a heating apparatus; and forming a predetermined pattern in the resist film by developing the heated wafer. The making a heated wafer includes: obtaining stage information that is information for specifying the exposure stage used in the making a wafer to be heated; and setting heating temperature of the heating apparatus based on the stage information individually for each of the plurality of exposure stages.

According to the present invention, it is possible to provide a manufacturing apparatus for a semiconductor device, a controlling method for the manufacturing apparatus, and a storage medium storing a control program for the manufacturing apparatus, which may suppress a deviation of a formed pattern dimension even in a case of using an exposure apparatus equipped with a plurality of exposure stages.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a structural diagram illustrating a semiconductor device manufacturing apparatus;

FIGS. 2A and 2B are a top view and a side view of each heating unit;

FIG. 3 is a flowchart illustrating a general flow of a manufacturing method for a semiconductor device;

FIG. 4 is a functional structural diagram illustrating a control unit;

FIG. 5 is a conceptual diagram illustrating contents of dimensional data;

FIG. 6 is a conceptual diagram illustrating an example of combination information;

FIG. 7 is a flowchart illustrating a controlling method for the semiconductor device manufacturing apparatus;

FIG. 8 is a structural diagram illustrating a semiconductor device manufacturing apparatus according to a variation example; and

FIG. 9 is a structural diagram illustrating a semiconductor device manufacturing apparatus according to another variation example.

### DETAILED DESCRIPTION OF THE PREFERRED EMBODIMENTS

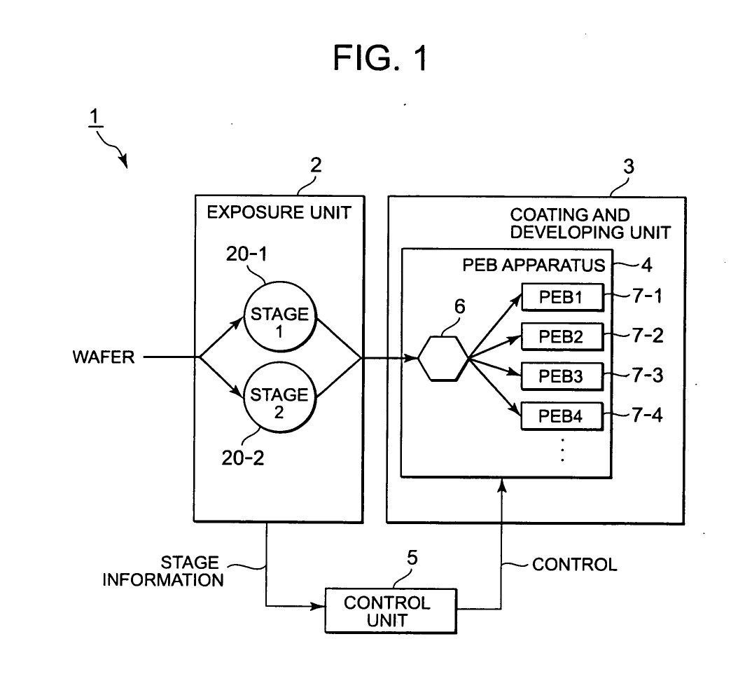

Hereinafter, an embodiment of the present invention is described with reference to the attached drawings. FIG. 1 is a structural diagram illustrating a semiconductor device manufacturing apparatus 1 according to this embodiment.

As illustrated in FIG. 1, the semiconductor device manufacturing apparatus 1 includes an exposure unit 2, a coating and developing unit 3, and a control unit 5. The coating and developing unit 3 includes a post exposure bake (PEB) apparatus 4 (heating apparatus) and a developing apparatus (not shown).

The exposure unit 2 is an apparatus for exposing a wafer on which a resist film is formed. Usually, the exposure unit 2 exposes the resist film formed on the wafer (to light) through a photomask on which a predetermined pattern is formed (so as to include a transparent part and an opaque part). As the resist, a chemical amplification resist is used. The exposure unit 2 has a plurality of (two) exposure stages 20 (20-1 and 20-2). Each of the exposure stages 20 is used for placing the wafer to be exposed. While the exposure process is performed on one exposure stage, measurement process or the like before exposure is performed on the other exposure stage. Thus, compared with an exposure unit having a single exposure stage, throughput of the exposure process may be improved. Such exposure unit is also called a dual stage exposure unit.

In addition, an exposure amount sensor (not shown) is attached to each of the exposure stages 20 of the exposure unit 2. When the exposure process is performed, the exposure amount sensor is used for obtaining a desired exposure amount.

The exposure unit 2 may be an immersion type exposure unit or a conventional exposure unit without liquid between a lens and a wafer, or another exposure unit of any generation. In this embodiment, an immersion type exposure unit is used as an example.

The coating and developing unit 3 is an apparatus for developing the wafer exposed by the exposure unit 2. In the coating and developing unit 3, a heating process of the wafer is first performed by the PEB apparatus 4. The heating process is performed for accelerating a reaction of the chemical amplification resist in the exposure process. The wafer heated by the PEB apparatus 4 (heated wafer) is developed by the coating and developing unit 3. By the development process, the resist on the wafer is patterned.

In addition, the coating and developing unit 3 also have a function of forming an antireflective film or the resist film on the wafer before exposure. In other words, the coating and developing unit 3 forms the antireflective film, the resist film, the protection film, and the like on the wafer, and then the wafer is sent to the exposure unit 2. The wafer is exposed by the exposure unit 2 and is again sent to the coating and developing unit 3. Then, the coating and developing unit 3 performs the development process.

The wafer after development process is etched by an etching apparatus (not shown) with a mask of the resist. After that, a removal apparatus removes the resist. Thus, a semiconductor device is obtained as a wafer on which a predetermined pattern is formed.

The PEB apparatus 4 includes an assignment mechanism 6 and a plurality of (e.g., four) heating units 7 (7-1 to 7-4). In the PEB apparatus 4, the wafer is assigned to one of the plurality of heating units 7 by the assignment mechanism 6. With the plurality of heating units 7, a plurality of wafers may be processed in a parallel manner, and hence throughput of the PEB apparatus 4 may be improved.

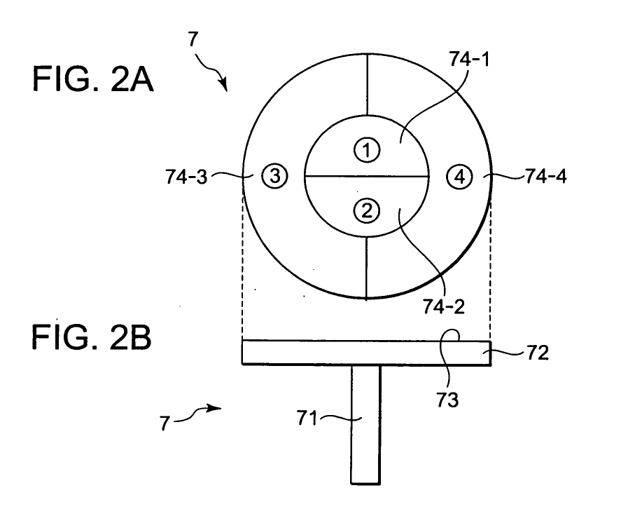

FIGS. 2A and 2B are a top view (2A) and a side view (2B) of each heating unit 7. As illustrated in FIGS. 2A and 2B, the heating units 7 each include a support rod 71 and a support plate 72 supported by the support rod 71. The support plate 72 has a mount surface 73 on which the wafer is placed. The mount surface 73 is divided into a plurality of (e.g., four) heating regions 74 (74-1 to 74-4). Temperatures of the plurality of heating regions 74 may be controlled independently of each other.

The control unit 5 is an apparatus for controlling the PEB apparatus 4. The control unit 5 sets heating temperature of the PEB apparatus 4. In addition, the control unit 5 decides which one of the PEB units 7 should be used for the wafer to be heated, so as to control the operation of the assignment mechanism 6.

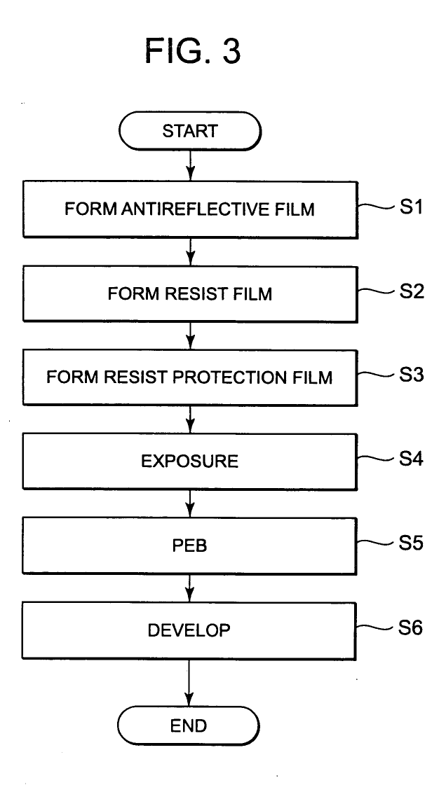

Next, a manufacturing method for a semiconductor device according to this embodiment is described. FIG. 3 is a flowchart illustrating a general flow of the manufacturing method for a semiconductor device according to this embodiment.

First, a wafer on which a film to be processed is formed is prepared, and an antireflective film is formed on the film to be processed (Step S1). Next, a chemical amplification resist film is formed on the antireflective film (Step S2). Further, a resist protection film is formed on the resist film. The resist protection film is formed when an immersion type exposure unit is used, for a purpose of preventing the resist film from being melted and flowing out in the exposure process (Step S3). The resist protection film is used for a purpose of anti-reflection in a non-immersion type exposure unit, and may not be used in some cases depending on the process. Next, the wafer is exposed by the exposure unit 2. In this case, the wafer is exposed by one of the exposure stage 20-1 and the exposure stage 20-2 (Step S4). Next, the wafer is sent from the exposure unit 2 to the coating and developing unit 5. In the coating and developing unit 5, the wafer is sent to one of the plurality of heating units 7 by the assignment mechanism 6. The wafer is heated by one of the plurality of heating units 7 (Step S5). After that, the wafer is developed by the developing apparatus (Step S6).

Here, in this embodiment, the heating temperature of the PEB apparatus 4 is adjusted by the control unit 5 so that a finally-formed pattern dimension agrees with a target dimension. By adjusting the heating temperature of the PEB apparatus 4, the resist pattern dimension obtained after the development process may be adjusted, and hence the actually-formed pattern dimension may be adjusted to a target value. However, in this embodiment, the wafer is exposed by one of the plurality of exposure stages 20. As described above, an individual variation of the exposure amount sensor may cause a deviation of the formed pattern dimension between wafers on different exposure stages.

The dimension deviation between exposure stages is a deviation due to the exposure process. Usually, it is considered that the deviation due to the exposure process may be corrected in the exposure process. In other words, it is considered that the exposure amount of each exposure stage 20 should be finely adjusted so that the difference in formed pattern dimension is eliminated.

However, a dimension variation when the exposure amount is changed may differ depending on a pattern pitch or size due to an influence of a so-called optical proximity effect. In other words, when a pattern dimension difference between the exposure stages 20 is to be eliminated by the exposure amount, it is necessary to take the pattern pitch or size into account, which causes a complicated correction process. In addition, the exposure amount may change an inclination of a cross section of the resist pattern. The inclination of the cross section of the resist pattern may affect the dimension after the etching process. In this way, it is very difficult to eliminate the pattern dimension difference between the exposure stages 20 by the exposure amount.

Therefore, in this embodiment, the control unit 5 decides the heating temperature in view of the exposure stage 20 that is used for the exposure. In other words, a dimension deviation due to the exposure process is corrected by the heating temperature in a post-exposure process. Thus, a pattern dimension deviation may be corrected accurately without being affected by the optical proximity effect or the like. Hereinafter, a structure and an operation of the control unit 5 are described in detail.

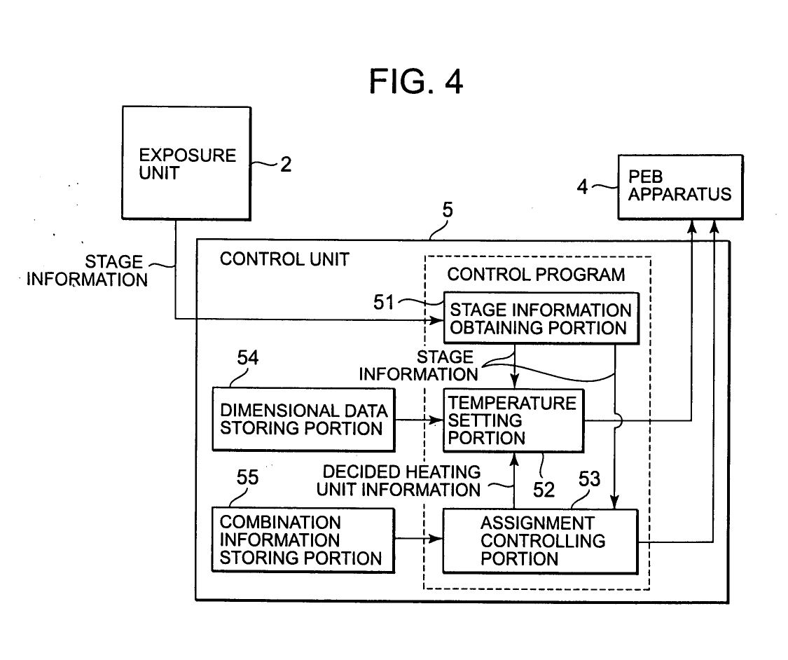

FIG. 4 is a functional structural diagram illustrating the control unit 5. As illustrated in FIG. 4, the control unit includes a stage information obtaining portion 51, a temperature setting portion 52, an assignment controlling portion 53; a dimensional data storing portion 54, and a combination information storing portion 55. Among those portions, the stage information obtaining portion 51, the temperature setting portion 52, and the assignment controlling portion 53 are realized by the control program installed in a computer. In addition, the dimensional data storing portion 54 and the combination information storing portion 55 are realized by a storage medium such as a hard disk.

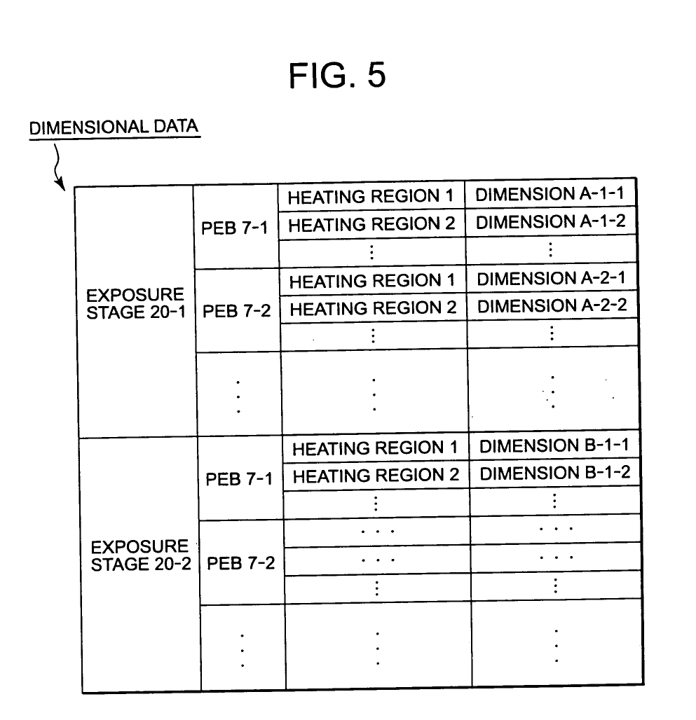

The dimensional data storing portion 54 stores actual measurement values of dimensions of the pattern formed on the wafer that has been processed as the dimensional data. FIG. 5 is a conceptual diagram illustrating contents of the dimensional data. As illustrated in FIG. 5, the dimensional data indicates a relationship among the exposure stage 20 used in the exposure process, the heating unit 7 used in the heating process, and dimensions of the formed pattern. In addition, the dimension is stored for each heating region of each heating unit 7. As the dimension, a resist pattern dimension after the development process may be used, or a dimension of the film to be processed after the etching process may be used.

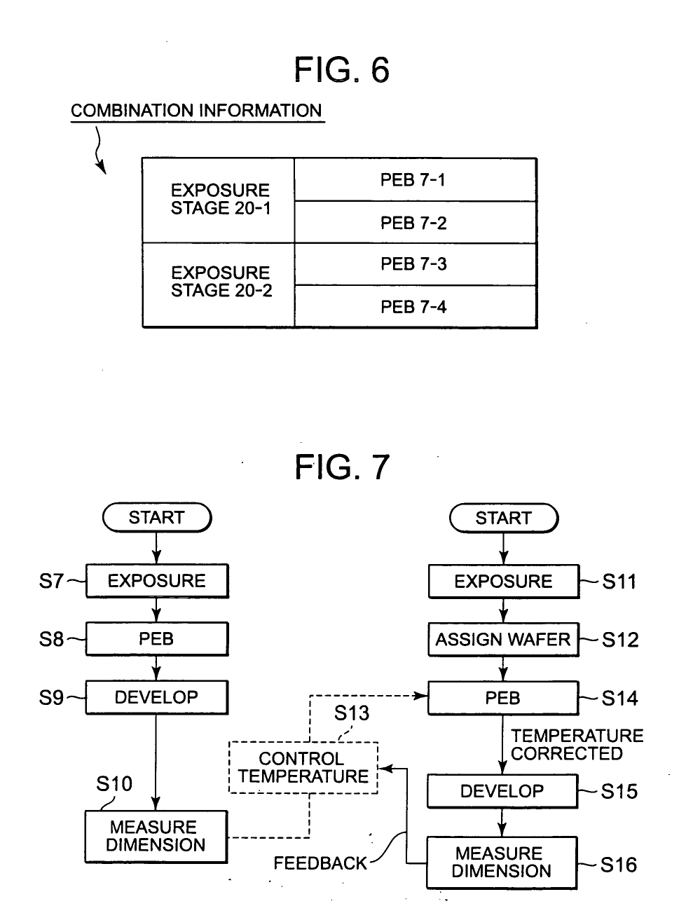

The combination information storing portion 55 stores a combination of the exposure stage and the heating unit that may be used as the combination information in advance. FIG. 6 is a conceptual diagram illustrating an example of the combination information. The example illustrated in FIG. 6 shows that the wafer exposed by the exposure stage 20-1 is heated by the heating unit 7-1 or 7-2, and the wafer exposed by the exposure stage 20-2 is heated by the heating unit 7-3 or 7-4.

The stage information obtaining portion 51 obtains a relationship between a wafer ID and an exposure stage 1D of the exposure stage used in the exposure process as stage information from the exposure unit 2. Then, the stage information obtaining portion 51 specifies the exposure stage used in the exposure process of the wafer to be heated and creates specific exposure stage information.

After obtaining the specific exposure stage information, the assignment controlling portion 53 refers to the combination information storing portion 55 so as to decide the heating unit 7 to be used for heating the wafer to be heated. The assignment controlling portion 53 controls the assignment mechanism 6 of the PEB apparatus 4 so that the wafer to be heated is sent to the decided heating unit 7. In addition, the assignment controlling portion 53 sends the information indicating the decided heating unit 7 as decided heating unit information to the temperature setting portion 52.

The temperature setting portion 52 receives the specific exposure stage information and the decided heating unit information, and then refers to the dimensional data storing portion 54 so as to calculate a temperature correction value of the heating unit 7 in such a manner that the formed pattern dimension agrees with the target dimension. Then, based on the temperature correction value, the heating temperature is set. The heating temperature is set individually for each of the used exposure stages. Further in this case, the temperature setting portion 52 sets the heating temperature for each heating region 74 of the heating unit 7. In the PEB apparatus 4, the temperature of each heating unit 7 is adjusted to become the heating temperature set by the temperature setting portion 52.

As described above, the heating temperature is set for each exposure stage, and hence an influence of a dimension deviation between exposure stages may be eliminated.

Next, a controlling method for the semiconductor device manufacturing apparatus according to this embodiment is described in detail. FIG. 7 is a flowchart illustrating the controlling method for the semiconductor device manufacturing apparatus according to this embodiment. By the process of Steps S7 to S10, the condition of the heating temperature is determined so that the dimensional data is created. After that, a process for an actual product is performed by the process of Steps S11 to S16.

(Determination of Condition of Heating Temperature)

First, a pilot wafer on which a resist protection film is formed is prepared. The pilot wafers in number corresponding to the number of combinations of the exposure stages 20 and the heating units 74 are prepared. Then, in each exposure stage 20, the exposure process of the pilot wafer is performed (Step S7).

Next, each heating unit 74 heats the pilot wafer (Step S8). After that, the pilot wafer is developed (Step S9).

After that, a resist pattern dimension on the pilot wafer is measured (Step S10). A plurality of positions in the resist pattern are measured respectively corresponding to the plurality of heating regions 74 for one pilot wafer. A result of the measurement is associated with the exposure stage 20, the heating unit 7, and the heating region 74 so as to be stored as the dimensional data in the dimensional data storing portion 54 of the control unit 5.

Note that it is possible to prepare a plurality of pilot wafers for one combination of the exposure stage 20 and the heating unit 74 in Step S7. In this case, in Step S10, an average value of the plurality of pilot wafers may be used as the dimensional data. If the average value is used, the dimensional data may be created more accurately.

(Process for Actual Product)

Next, the exposure unit 2 performs the exposure process of the wafer to be processed. Here, the exposure unit 2 creates a relationship between the processed wafer and the used exposure stage as the stage information, and sends it to the control unit 5 (Step S11).

Next, in the control unit 5, the assignment controlling portion 53 decides the heating unit 74 to be used for the wafer to be heated based on the stage information. The assignment controlling portion 53 controls the assignment mechanism 6 so that the wafer to be heated is sent to the decided heating unit 74 (Step S12).

Next, the control unit 5 calculates the temperature correction value based on the dimensional data so that the formed pattern dimension agrees with a target value. Then, the control unit 5 sets the heating temperature based on the temperature correction value (Step S13). Next, in the PEB apparatus 4, the wafer to be heated is heated (Step S14).

In this case, the heating temperature is individually set for each of the exposure stages 20 used in the exposure process. Therefore, even if a difference in formed pattern dimension occurs among the exposure stages 20, influence of this difference may be eliminated.

In addition, the control unit 5 sets the heating temperature individually for each of the heating units 7.

Therefore, even if a difference in formed pattern dimension is caused by the individual variation among the plurality of heating units 74, influence of this difference may be eliminated.

Further, the control unit 5 sets the heating temperature individually for each of the plurality of heating regions 74. In the heating unit 7, heating degree may be different depending on the position, or the formed pattern dimension may have a difference due to an influence of the process before lithography. In other words, a variation of the pattern dimension may occur in the surface within the same wafer. By setting the heating temperature individually for each of the plurality of heating regions 74, a variation of the pattern dimension in the surface may be eliminated.

After that, the wafer heated by the PEB apparatus 4 is developed by the developing apparatus (Step S15). After the development process, a dimension of the formed resist pattern is measured (Step S16). The measurement result is sent to the control unit 5 as necessity, and the dimensional data in the dimensional data storing portion 54 is updated. In other words, the measurement result of the dimension is fed back to the control unit 5.

As described above, according to this embodiment, the heating temperature is set individually for each of the exposure stages of the exposure unit 2. Therefore, a difference in formed pattern dimension due to a difference between the exposure stages may be absorbed by the operation of the PEB apparatus 4.

Further, in this embodiment, the combination of the exposure stage and the heating unit that may be used is set as the combination information in advance. In other words, the combination is limited. Thus, the control unit 5 does not need to calculate the temperature correction value for every combination of the exposure stage and the heating unit. Because the combination is limited, a load on the control unit 5 concerning the calculation process of the temperature correction value may be reduced.

Note that this embodiment describes the case where the control unit 5 is disposed separately from the exposure unit 2 and the coating and developing unit 3. However, a part of functions of the control unit 5 may be incorporated in the exposure unit 2 or in the coating and developing unit 3.

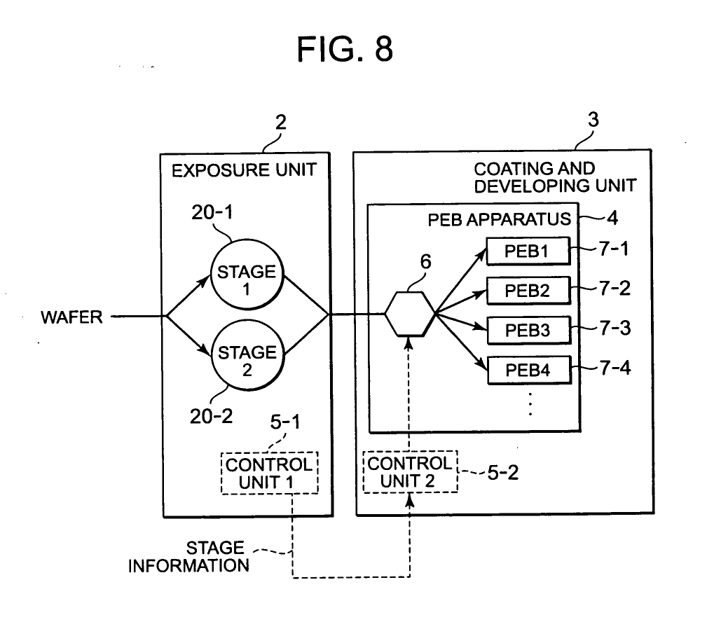

For instance, it is also possible to adopt the structure illustrated in FIG. 8 as a variation example. In the variation example illustrated in FIG. 8, the control unit 5 includes a control portion 5-1 incorporated in the exposure unit 2 and a control portion 5-2 incorporated in the coating and developing unit 3. The control portion 5-1 functions as the stage information obtaining portion 51, and the obtained stage information is sent to the control portion 5-2 by wired or wireless communication. On the other hand, the control portion 5-2 functions as the temperature setting portion 52, the assignment controlling portion 53, the dimensional data storing portion 54, and the combination information storing portion 55.

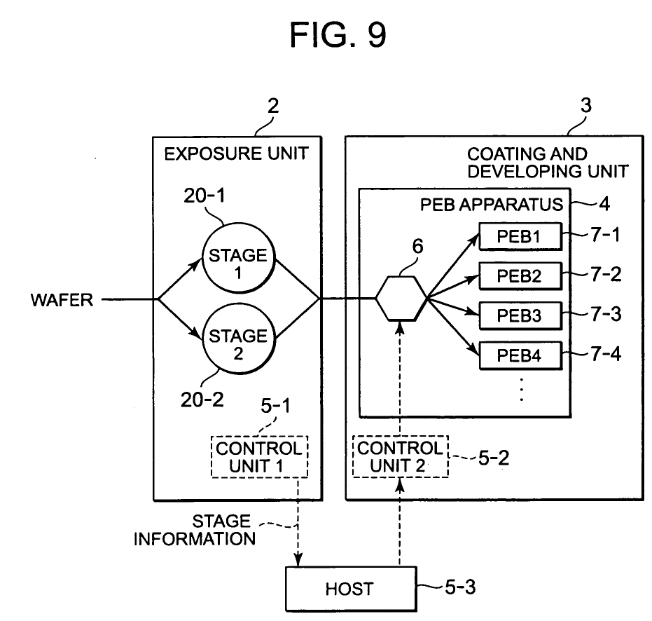

In addition, it is also possible to adopt the structure illustrated in FIG. 9 as another variation example. In the variation example illustrated in FIG. 9, the control unit 5 is constituted of a control portion 5-1 incorporated in the exposure unit 2, a control portion 5-2 incorporated in the coating and developing unit 3, and a host computer 5-3 disposed separately from the exposure unit 2 and the coating and developing unit 3. The control portion 5-1 functions as the stage information obtaining portion 51. The control portion 5-2 functions as the assignment controlling portion 53. The host computer 5-3 functions as the temperature setting portion 52, the dimensional data storing portion 54, and the combination information storing portion 55.

It is apparent that the present invention is not limited to the above embodiments, but may be modified and changed without departing from the scope and spirit of the invention.

What is claimed is:

1. A semiconductor device manufacturing apparatus, comprising:
a stage information obtaining portion for obtaining stage information that is information for specifying an exposure stage used in an exposure process of a wafer to be heated from an exposure unit including a plurality of exposure stages on which the wafer is placed; and
a temperature setting portion for setting heating temperature of a heating apparatus for heating the wafer to be heated,
wherein the temperature setting portion sets the heating temperature based on the stage information individually for each of the plurality of exposure stages.

2. A semiconductor device manufacturing apparatus according to claim 1, wherein:
the heating apparatus includes a heating unit having a mount surface on which the wafer to be heated is placed;
the mount surface is divided into a plurality of heating regions having temperatures that may be controlled independently of each other; and
the temperature setting portion sets the heating temperature individually for each of the plurality of heating regions.

3. A semiconductor device manufacturing apparatus according to claim 1, wherein the temperature setting portion obtains dimensional data that is data containing a relationship between each of the exposure stages and a dimension of a pattern formed on a processed wafer that is processed by the exposure unit and the heating apparatus, and sets the heating temperature based on the dimensional data so that the dimension of the pattern formed on the wafer to be heated agrees with a target dimension set in advance.

4. A semiconductor device manufacturing apparatus according to claim 1, wherein:
the heating apparatus includes a plurality of heating units; and
the temperature setting portion sets the heating temperature individually for each of the plurality of heating units.

5. A semiconductor device manufacturing apparatus according to claim 4, further comprising an assignment controlling portion for determining a heating unit for heating the wafer to be heated among the plurality of heating units by referring to combination information indicating a usable combination of the exposure stage and the heating unit, the combination information being set in advance,
wherein the temperature setting portion sets the heating temperature only for the combination indicated in the combination information.

6. A controlling method for a semiconductor device manufacturing apparatus, comprising:
obtaining stage information that is information for specifying an exposure stage used in an exposure process of a wafer to be heated from an exposure unit including a plurality of exposure stages on which the wafer is placed; and
setting heating temperature of a heating apparatus for heating the wafer to be heated based on the stage information individually for each of the plurality of exposure stages.

7. A controlling method for a semiconductor device manufacturing apparatus according to claim 6, wherein:
the heating apparatus includes a heating unit having a mount surface on which the wafer to be heated is placed;
the mount surface is divided into a plurality of heating regions having temperatures that may be controlled independently of each other; and
the setting heating temperature individually includes setting the heating temperature for each of the plurality of heating regions.

8. A controlling method for a semiconductor device manufacturing apparatus according to claim 6, wherein the setting heating temperature individually includes:
obtaining dimensional data that is data containing a relationship between each of the exposure stages and a dimension of a pattern formed on a processed wafer that is processed by the exposure unit and the heating apparatus; and
setting the heating temperature based on the dimensional data so that the dimension of the pattern formed on the wafer to be heated agrees with a target dimension set in advance.

9. A controlling method for a semiconductor device manufacturing apparatus according to claim 6, wherein:
the heating apparatus includes a plurality of heating units; and
the setting heating temperature individually includes setting the heating temperature individually for each of the plurality of heating units.

10. A controlling method for a semiconductor device manufacturing apparatus according to claim 9, further comprising determining a heating unit for heating the wafer to be heated among the plurality of heating units by referring to combination information indicating a usable combination of the exposure stage and the heating unit, the combination information being set in advance,
wherein the setting heating temperature individually further includes setting the heating temperature only for the combination indicated in the combination information.

11. A storage medium storing a control program for a semiconductor device manufacturing apparatus to be executed by a computer for realizing the controlling method for a semiconductor device manufacturing apparatus according to claim 6.

12. A manufacturing method for a semiconductor device, comprising:
making a wafer to be heated by exposing a wafer on which a resist film is formed, with an exposure unit including a plurality of exposure stages on which the wafer is placed;
making a heated wafer by heating the wafer to be heated with a heating apparatus; and
forming a predetermined pattern in the resist film by developing the heated wafer,
wherein the making a heated wafer includes:
obtaining stage information that is information for specifying the exposure stage used in the making a wafer to be heated; and
setting heating temperature of the heating apparatus based on the stage information individually for each of the plurality of exposure stages.
